(19) United States
(12) Patent Application Publication
(10) Pub. No.: US 2021/0384033 A1
(43) Pub. Date: Dec. 9, 2021

(54) SHOWER PLATE, SUBSTRATE TREATMENT DEVICE, AND SUBSTRATE TREATMENT METHOD

(71) Applicant: ASM IP Holding B.V., Almere (NL)

(72) Inventor: Ryo Miyama, Tokyo (JP)

(21) Appl. No.: 17/334,797

(22) Filed: May 31, 2021

Related U.S. Application Data
(60) Provisional application No. 63/034,392, filed on Jun. 3, 2020.

(51) Int. Cl. H01L 21/263; C23C 16/56; C23C 4/18

(52) U.S. Cl. CPC H01L 21/263; C23C 4/18; C23C 16/56

(57) ABSTRACT

Examples of a shower plate include a body part of a plate-like conductor having a plurality of through holes, the body part being provided with a surface treated part on at least a part of a lower surface, the surface treated part having been subjected to surface treatment, thereby causing two or more regions having different emissivities to exist on the lower surface, and a flange surrounding the body part.

### CROSS-REFERENCE TO RELATED APPLICATIONS

This application claims the benefit of and priority to U.S. Provisional Application No. 63/034,392, filed on Jun. 3, 2020 in the United States Patent and Trademark Office, the disclosure of which is incorporated herein in its entirety by reference.

### FIELD

Examples are described which relate to a shower plate, a substrate treatment device, and a substrate treatment method.

### BACKGROUND

A semiconductor process for treating a substrate requires an improved in-plane uniformity of a substrate in a process result. In order to improve the in-plane uniformity of a substrate in a process result, the in-plane distribution of a wafer temperature may be controlled. For example, the in-plane distribution of the wafer temperature can be controlled by dividing a wafer stage or a susceptor into multiple zones to allow temperature control of each of the zones. However, a structure for varying the temperatures of a plurality of stage zones is so complicated that troubles easily occur and in addition costs increase.

### SUMMARY

Some examples described herein may address the above-described problems. Some examples described herein may provide a shower plate, a substrate treatment device, and a substrate treatment method that are suitable for controlling the in-plane distribution of substrate temperature.

In some examples, a shower plate includes a body part of a plate-like conductor having a plurality of through holes, the body part being provided with a surface treated part on at least a part of a lower surface, the surface treated part having been subjected to surface treatment, thereby causing two or more regions having different emissivities to exist on the lower surface, and a flange surrounding the body part.

### BRIEF DESCRIPTION OF THE DRAWINGS

FIG. 1 is a cross-sectional view that illustrates a configuration example of a substrate treatment device;

FIG. 2 is a cross-sectional view of the shower plate and the susceptor;

FIG. 3 is a bottom view of the shower plate;

FIG. 4 is a cross-sectional view of a surface treated part according to another example;

FIG. 5 is a cross-sectional view of a surface treated part according to another example;

FIG. 6A shows an example of the surface treated part;

FIG. 6B shows another example of the surface treated part;

FIG. 6C shows another example of the surface treated part;

FIG. 6D shows another example of the surface treated part;

FIG. 6E shows another example of the surface treated part;

FIG. 6F shows another example of the surface treated part;

FIG. 6G shows another example of the surface treated part;

FIG. 6H shows another example of the surface treated part;

FIG. 7 illustrates an example of a substrate treatment method;

FIG. 8 is a graph showing that a substrate temperature is adjusted by surface treatment;

FIG. 9 is another graph showing that the substrate temperature is adjusted by surface treatment; and

FIG. 10 shows the amount of radiant heat applied from a substrate to a shower plate.

### DETAILED DESCRIPTION

A shower plate, a substrate treatment device, and a substrate treatment method will be described with reference to drawings. Identical or corresponding components are denoted by identical reference signs and repeated descriptions thereof may be omitted.

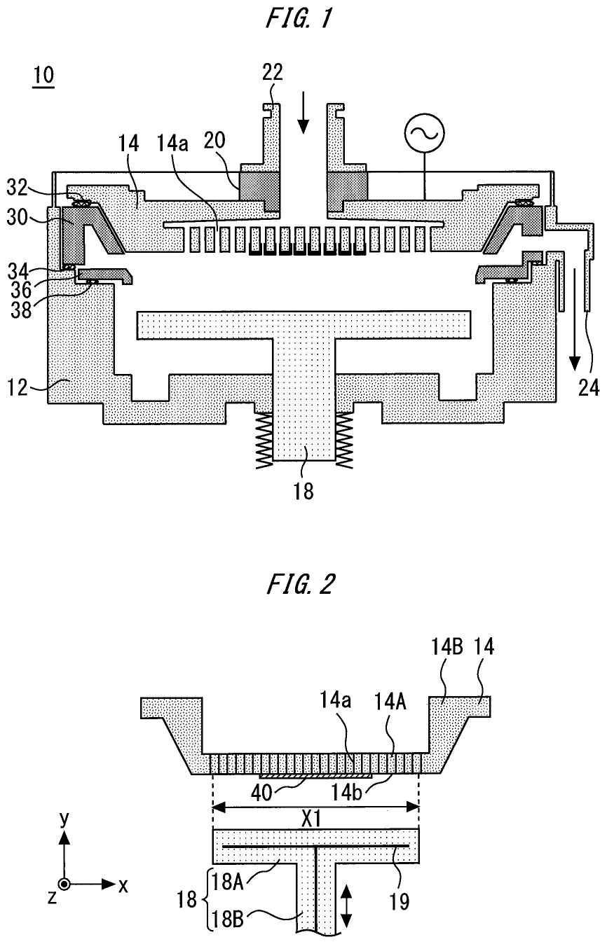

FIG. 1 is a cross-sectional view that illustrates a configuration example of a substrate treatment device. A substrate treatment device 10 includes a chamber (Reactor Chamber) 12 that is formed of, for example, metal. In the chamber 12, a shower plate 14 is provided. The shower plate 14 is supplied with electric power such as RF power. The shower plate 14 has through holes 14a formed therein. The shower plate 14 is constituted of a single component or by combination of a plurality of components. In one example, a material of the shower plate 14 is aluminum, aluminum alloy, or silicon. In another example, the shower plate 14 can be of any conductor.

In the chamber 12, a susceptor 18 that faces the shower plate 14 is provided. The susceptor 18 can be electrically connected with the chamber 12 for grounding, for example Thus, the shower plate 14 and the susceptor 18 provide a parallel plate structure.

To the shower plate 14, a gas supply pipe 22 is connected via an insulating component 20. The gas supply pipe 22 supplies gas between the shower plate 14 and the susceptor 18. The insulating component 20 is formed of an insulator in order to electrically isolate the shower plate 14 from the gas supply pipe 22.

On a side surface of the chamber 12, a gas exhaust part 24 is provided. The gas exhaust part 24 is provided so as to exhaust gas that has been used for substrate treatment. Therefore, a vacuum pump can be connected to the gas exhaust part 24.

Between the shower plate 14 and the chamber 12, an exhaust duct 30 is provided. The exhaust duct 30 is formed of, for example, ceramic. The exhaust duct 30 is mounted on the chamber 12 via an O ring 34. The O ring 34 is compressed to an appropriate extent by the weight of the exhaust duct 30. The shower plate 14 is mounted on the exhaust duct 30 via an O ring 32. The O ring 32 is compressed to an appropriate extent by the weight of the shower plate 14.

In addition, a flow control ring (FCR) 36 is provided at a fixed interval from the exhaust duct 30. The FCR 36 is mounted on the chamber 12 via an O ring 38. The O ring 38 is compressed to an appropriate extent by the weight of the FCR 36.

In one example, the exhaust duct 30 electrically isolates the shower plate 14 which is supplied with electric power from the chamber 12 having a GND potential. To this end, the exhaust duct 30 is formed of an insulator. The exhaust duct 30 and the FCR 36 conduct the gas which has been used for substrate treatment and the like from between the shower plate 14 and the susceptor 18 to the gas exhaust part 24. Therefore, in one example, the exhaust duct 30 and the FCR 36 are annularly formed so as to surround the susceptor 18 in a plan view, conducting the gas to the gas exhaust part 24.

FIG. 2 is a cross-sectional view that illustrates a configuration example of the shower plate 14 and the susceptor 18. The shower plate 14 includes a body part 14A and a flange 14B. The body part 14A is a plate-like conductor having a plurality of through holes 14a. In an example of FIG. 2, the body part 14A is positioned directly above the susceptor 18 and has a width of X1. On at least a part of a lower surface 14b of the body part 14A, a surface treated part 40 which has been subjected to surface treatment is provided. The surface treated part 40 is, in the example of FIG. 2, an oxide film on a part of the lower surface 14b. This oxide film can be formed by oxidizing the body part 14A by, for example, anodic oxidation. The oxide film is, for example, Al₂O₃ or SiO₂. In one example, the thickness of the oxide film constituting the surface treated part 40 is less than 50 μm. In another example, the thickness of the oxide film is 1 μm or less. The surface treated part 40 is provided on at least a part of the lower surface 14b of the body part 14A without closing the through holes 14a.

There is the surface treated part 40 on a part of the lower surface 14b. On the lower surface 14b, accordingly, both the surface treated part 40 and the body part 14A are exposed. That is, two regions having different emissivities exist on the lower surface 14b. In this example, the emissivity of the surface treated part 40 is higher than that of the body part 14A. The higher the emissivity is, the more heat is absorbed; the lower the emissivity is, the less heat is absorbed.

In another example, three or more regions having different emissivities can be provided on the lower surface 14b. For example, two or more oxide films having different thicknesses can be provided as the surface treated part. More specifically, a first oxide film, a second oxide film thicker than the first oxide film, and the body part 14A are exposed on the lower surface 14b, thereby allowing three regions having different emissivities to be provided.

The flange 14B surrounds the body part 14A. In one example, the flange 14B, which is formed integrally with the body part 14A, is a ring-shaped conductor that surrounds the body part 14A. The flange 14B can be used to fix the shower plate 14.

The susceptor 18 includes: a stage 18A; a shaft 18B that supports the stage 18A; and a heater 19 that heats the stage 18A. The stage 18A faces the lower surface 14b. In one example, the shaft 18B can be moved in both arrow directions in FIG. 2 by, for example, a motor. As the heater 19, any heater that is constituted so as to heat the stage can be adopted. The heater 19 may be embedded in the stage 18A; or may be positioned at a lower part or side part of the stage 18A.

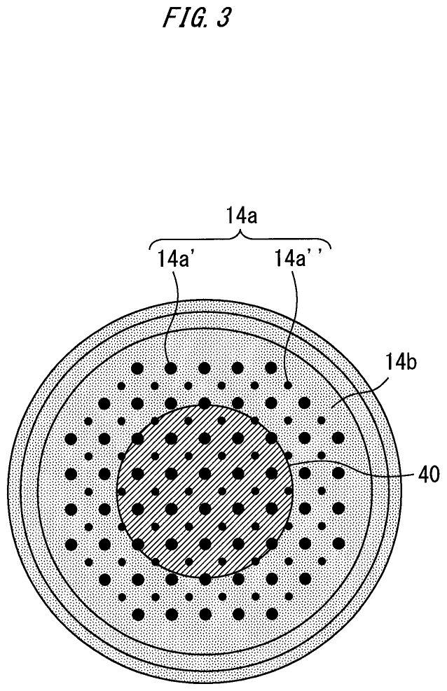

FIG. 3 is a bottom view of the shower plate 14. In one example, the through holes 14a include first through holes 14a′ and second through holes 14a″. The first through holes 14a′ and the second through holes 14a″ are provided so as to supply different gases to the substrate. In the example, the surface treated part 40 is formed in a center of the lower surface 14b.

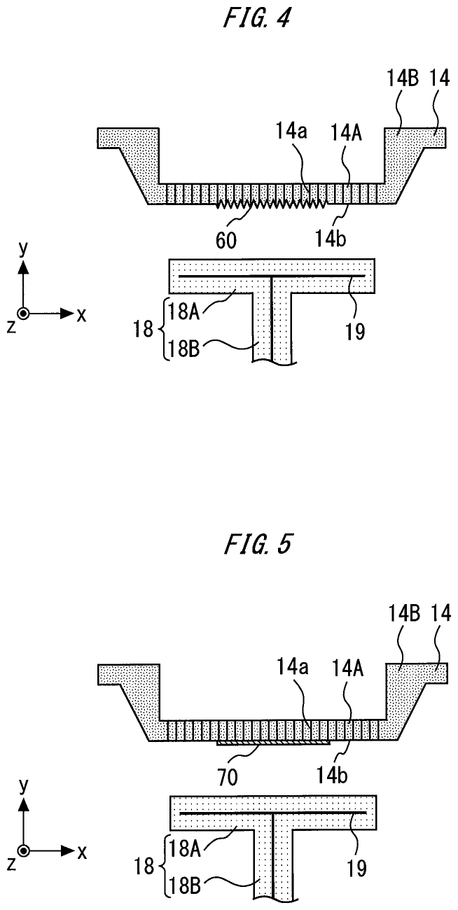

FIG. 4 is a cross-sectional view that shows a surface treated part according to another example. FIG. 4 illustrates a rough surface 60 that is provided as the surface treated part. The rough surface 60 exhibits increased surface roughness as compared with a periphery of the surface treated part. In this example, the surface roughness of the rough surface 60 has larger surface roughness than the original surface roughness of the shower plate 14. The rough surface 60 can be formed by, for example, blast treatment. The larger the surface roughness of the lower surface 14b is, the larger a surface area becomes. Thus, increasing the surface roughness allows emissivity to be enhanced.

In another example, three or more regions having different degrees of surface roughness are provided on the lower surface 14b and thereby, three or more regions having different emissivities can be provided.

FIG. 5 is a cross-sectional view that shows a surface treated part in yet another example. FIG. 5 illustrates a coating 70 that is provided as the surface treated part. A material of the coating 70 is different from a material of the body part 14A. The coating 70 is provided without closing the through holes 14a. In one example, the material of the coating 70 is, for example, Y₂O₃ or YF₃. Teflon can also be provided as the coating 70. In one example, the emissivity of the coating 70 is higher than the emissivity of the body part 14A including aluminum. In another example, the material of the coating can be any material that is different from that of the body part 14A. For example, the coating can be formed by thermal spraying or CVD. The thickness of the coating is freely determined; it can be less than 50 μm or equal to or less than 1 μm, for example.

When a coating of a material that is different from that of the body part is provided as the surface treated part, two or more coatings having different thicknesses may be provided. For example, a first coating and a second coating that is formed at an area different from the first coating so as to be thicker than the first coating can be provided. In this case, three regions having different emissivities can be provided on the lower surface 14b.

As an example of the surface treated part, the oxide film, the rough surface, and the coating have been described; however, in another example, a surface treated part of another embodiment can be provided.

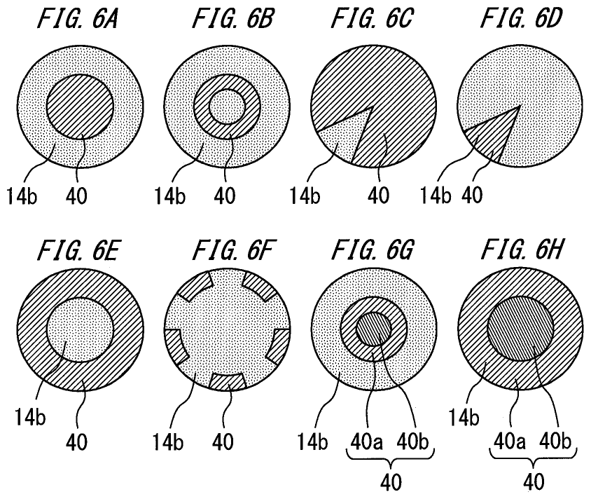

FIGS. 6A to 6H are bottom surface views that illustrates arrangement examples of the surface treated part. FIG. 6A is a view that illustrates an example of providing the surface treated part 40 circularly in a center of the lower surface 14b. FIG. 6B is a view that illustrates an example of providing the surface treated part 40 in a ring shape on the lower surface 14b. FIG. 6C is a view that illustrates an example of providing the surface treated part 40 on most of the lower surface 14b except a specific sector. FIG. 6D is a view that illustrates an example of providing the surface treated part 40 in a sector shape on the lower surface 14b. FIG. 6E is a view that illustrates an example of providing the surface treated part 40 annularly along an outer edge of the lower surface 14b. FIG. 6F is a view that illustrates an example of providing the surface treated part 40 intermittently along the outer edge of the lower surface 14b. FIG. 6G is a view that illustrates an example of providing a first part 40a and a second part 40b as the surface treated part 40. Although both the first part 40a and the second part 40b have been subjected to surface treatment, their emissivities are different. In this example, the emissivity of the second part 40b is higher than that of the first part 40a. The emissivities of the first part 40a and the second part 40b are higher than the emissivity of the body part 14A. Therefore, in the example of FIG. 6G, three regions having different emissivities are provided. FIG. 6H is a view that illustrates an example of providing the surface treated part 40 entirely on the lower surface 14b. The surface treated part 40 includes a first part 40a and a second part 40b that have different emissivities. The emissivity of the second part 40b is higher than that of the first part 40a, and the emissivity of the first part 40a is higher than that of the body part 14A. FIGS. 6A to 6H are merely illustrations and the surface treated part can be formed anywhere on the lower surface 14b.

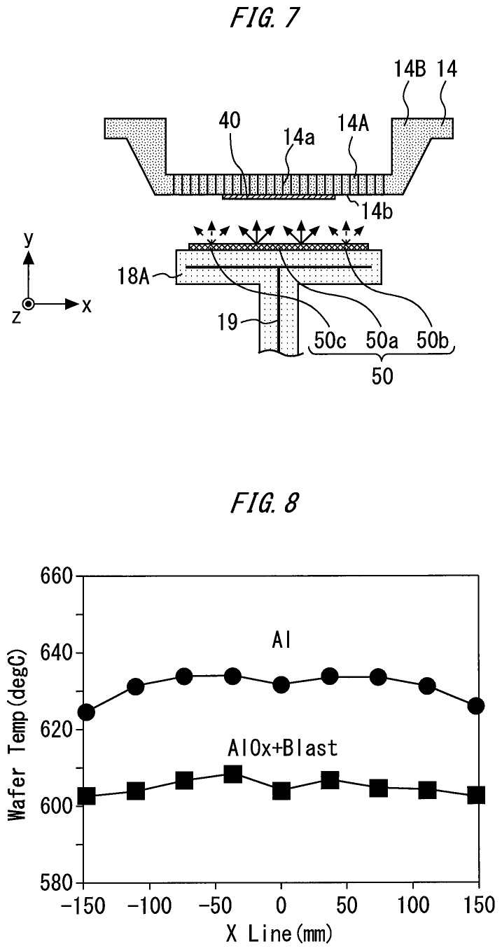

FIG. 7 illustrates an example of a substrate treatment method. In this substrate treatment method, first, a substrate 50 is placed on the stage 18A. The substrate 50 is to be processed in the substrate treatment device. The lower surface 14b of the shower plate 14 faces the stage and the substrate 50. The substrate 50 is, for example, a wafer. The substrate 50 includes: a directly below part 50a that is positioned directly below the surface treated part 40; and a non directly-below parts 50b and 50c that are positioned directly below a part other than the surface treated part 40 of the body part 14A.

Next, for example, while the stage 18A is heated to 400° C. or higher by the heater 19, plasma treatment is applied to the substrate 50. In one example, plasma treatment is applied to the substrate 50 by supplying a high frequency power to the shower plate 14 while supplying gas onto the stage 18A via the through holes 14a. At this time, the surface treated part 40 which has been subjected to surface treatment exists on at least a part of the lower surface 14b and therefore, two more regions having different emissivities exist on the lower surface 14b. This makes the degree of cooling of the substrate 50 differ depending on an area of the substrate 50. Specifically, the directly below part 50a of the substrate 50 faces the surface treated part 40 having high emissivity and therefore, heat is easily dissipated. On the other hand, the non directly-below parts 50b and 50c of the substrate 50 face the body part 14A having low emissivity and therefore, heat is difficult to dissipate. In FIG. 7, arrows with solid lines indicate that the amount of heat dissipation from the directly below part 50a is large, and arrows with broken lines indicate that the amount of heat dissipation from the non directly-below parts 50b and 50c is small. Therefore, in this example, as far as contribution of the shower plate 14 is concerned, heat is easily dissipated at the directly below part 50a and heat is difficult to dissipate at the non directly-below parts 50b and 50c. Thus, providing the surface treated part allows substrate temperature distribution to be controlled. Such a process as described above can be provided as, for example, high-temperature plasma treatment.

In a parallel plate structure of the stage 18A and the shower plate 14 in one example, a center of the substrate tends to become higher in temperature than an outer edge of the substrate. Therefore, a surface treated part having high emissivity is provided directly above the center of the substrate, so that the temperature of the substrate can be brought closer to uniformity than when the surface treated part is not provided.

In another example, a process in which a temperature difference is intentionally provided for the substrate may be adopted. In this case, in order to obtain an intended temperature difference, the shape of the surface treated part can be adjusted.

As such, the surface treated part is provided to divide the lower surface of the shower plate into multiple zones for each emissivity, so that the heat dissipated from the substrate is controlled within a plane. The surface treated part 40 has a higher emissivity or a lower emissivity than an area other than the surface treated part on the lower surface 14b, depending on the material or shape of the surface treated part. Since the surface treated part can be easily provided by processing the lower surface of the shower plate, it provides a cost advantage.

FIG. 8 is a graph showing that a substrate temperature is adjusted by surface treatment. Circles show an example of the in-plane distribution of the substrate temperature when a shower plate made of Al is used. Rectangles show an example of the in-plane distribution of the substrate temperature when another shower plate made of Al is used. This shower plate has an oxide film formed entirely thereon and further, blast treatment applied entirely thereto. In these examples, the same process has been adopted. Specifically, Ar is supplied at 3 slm into the chamber; an in-chamber pressure is set to 600 Pa, a gap between the stage and the shower plate is set to 14.5 mm; and the temperatures of the susceptor, shower plate, and chamber wall surface are set to 650° C., 240° C., and 160° C., respectively. According to FIG. 8, it is found that a substrate temperature can be decreased by providing a surface treated part including a combination of an oxide film and a rough surface.

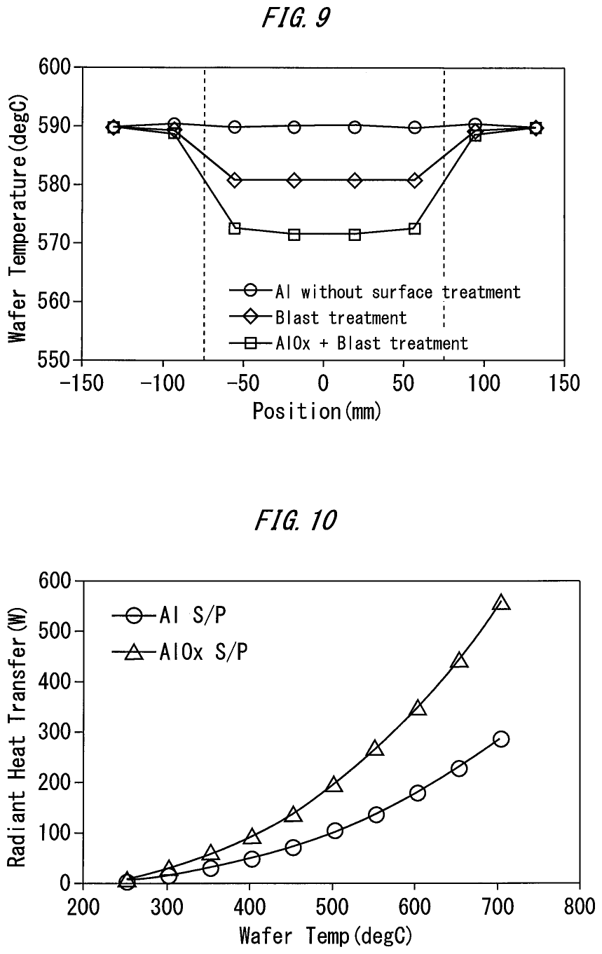

FIG. 9 is another graph showing that the substrate temperature is adjusted by surface treatment. FIG. 9 shows temperature distributions of a substrate having a diameter of 300 mm when treatment is applied to the substrate by using three different shower plates. Data indicated by circles shows an example of the in-plane distribution of the substrate temperature when a shower plate made of Al is used. Data indicated by rhombuses shows an example of the in-plane distribution of the substrate temperature when another shower plate made of Al is used. This shower plate has a rough surface formed by blast treatment in a region having a diameter of 150 mm in a center of a lower surface thereof. Data indicated by rectangles shows an example of the in-plane distribution of the substrate temperature when another shower plate made of Al is used. This shower plate has an oxide film formed and further a rough surface formed by blast treatment in a region having a diameter of 150 mm in a center of a lower surface thereof. In any of the examples, the Al material is exposed on an outer edge side of the lower surface of the shower plate. All the data in FIG. 9 has been obtained by simulation.

According to FIG. 9, it is found that a substrate temperature can be decreased by forming a rough surface and the substrate temperature can be further decreased by forming a rough surface on an oxide film. The emissivity of the shower plate made of Al, which is indicated by circles, is 0.1 and the emissivity of the Al rough surface is 0.2, and the emissivity of the rough surface of the oxide film is 0.3.

FIG. 10 is a graph showing the amount of radiant heat applied from a substrate to a shower plate. Results in FIG. 10 have been obtained by simulation. Data indicated by circles shows data that is obtained in connection with a shower plate on whose entire surface aluminum is exposed. The emissivity of aluminum is assumed to be 0.1. Data indicated by triangles shows data that is obtained in connection with a shower plate whose entire surface is covered with an oxide film (AlOₓ). The emissivity of the oxide film is assumed to be 0.2. According to FIG. 10, it is found that especially in a high temperature region where a substrate temperature is 400° C. or higher, a difference in the amount of radiant heat from a substrate to a shower plate becomes larger. In other words, a temperature reduction effect of a substrate due to providing a surface treated part is more pronounced with higher substrate temperature.

1. A shower plate, comprising:
a body part of a plate-like conductor having a plurality of through holes, the body part being provided with a surface treated part on at least a part of a lower surface, the surface treated part having been subjected to surface treatment, thereby causing two or more regions having different emissivities to exist on the lower surface; and
a flange surrounding the body part.

2. The shower plate according to claim 1, wherein the surface treated part is an oxide film.

3. The shower plate according to claim 1, wherein the surface treated part includes two or more oxide films having different thicknesses.

4. The shower plate according to claim 2, wherein a thickness of the oxide film is less than 50 μm.

5. The shower plate according to claim 2, wherein a thickness of the oxide film is 1 μm or less.

6. The shower plate according to claim 1, wherein the surface treated part has a rough surface, surface roughness of the surface treated part being increased as compared with a periphery of the surface treated part.

7. The shower plate according to claim 1, wherein the surface treated part is a coating of a material different from a material of the body part.

8. The shower plate according to claim 1, wherein the surface treated part includes two or more coatings having different thicknesses of a material different from a material of the body part.

9. The shower plate according to claim 7, wherein the material of the coating includes Y₂O₃ or YF₃.

10. A substrate treatment device, comprising:
the shower plate according to claim 1; and
a susceptor including a stage and a heater, the stage facing the lower surface, the heater being constituted so as to heat the stage.

11. A substrate treatment method, comprising:
placing a substrate on a stage; and
applying plasma treatment to the substrate with a lower surface of a body part of a shower plate facing the stage while heating the stage to 400° C. or higher,
wherein, a surface treated part is provided on at least a part of the lower surface, the surface treated part having been subjected to surface treatment, thereby causing two or more regions having different emissivities to exist on the lower surface.

12. The substrate treatment method according to claim 11, wherein
the surface treated part has a higher emissivity than an area other than the surface treated part on the lower surface.
